(19) United States
(12) Patent Application Publication
(10) Pub. No.: US 2016/0120046 A1
(43) Pub. Date: Apr. 28, 2016

(54) HOUSING, ELECTRONIC DEVICE USING SAME, AND METHOD FOR MAKING SAME

(71) Applicants: SHENZHEN FUTAIHONG PRECISION INDUSTRY CO., LTD., Shenzhen (CN); FIH (HONG KONG) LIMITED, Kowloon (HK)

(72) Inventors: WU-ZHENG OU, New Taipei (TW); CHANG-HAI GU, Shenzhen (CN); DAN WANG, Shenzhen (CN); XIAO-KAI LIU, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 14/712,131

(22) Filed: May 14, 2015

(30) Foreign Application Priority Data
Oct. 23, 2014 (CN) 201410570109.9

(51) Int. Cl. H05K 5/00; B29B 11/04; H05K 5/02; B29C 45/14; H01Q 1/22; H01Q 9/04

(52) U.S. Cl. CPC H05K 5/0086; H01Q 1/22; H01Q 9/04; H05K 5/0217; B29C 45/14639; B29B 11/04; B29C 2045/14868; B29L 2031/3481

(57) ABSTRACT

A housing includes a base. The base has a number of main portions separated by one or more portions having a number of openings formed therein. Each of the number of openings has a metal strip therebetween thereby forming a series of openings and metal strips. Each of the openings has non-conductive members being formed therein. The metal strips are fixed together by the non-conductive members to form a metal strip assembly. The metal strips and the main portions are fixed together by the non-conductive members.

### FIELD

The subject matter herein generally relates to a housing, an electronic device using the housing, and a method for making the housing.

### BACKGROUND

Metal housings are widely used for electronic devices.

### BRIEF DESCRIPTION OF THE FIGURES

Implementations of the present technology will now be described, by way of example only, with reference to the attached figures.

FIG. 1 is an isometric view of an electronic device, according to an exemplary embodiment.

FIG. 2 is a partial, isometric view of a housing of the electronic device shown in FIG. 1.

FIG. 3 is similar to FIG. 2, but shown from another angle.

FIG. 4 is an exploded, isometric view of the housing shown in FIG. 1.

FIG. 5 is a cross-sectional view of the housing along line V-V of FIG. 2.

FIG. 6 is an enlarged view of the housing of circled portion VI in FIG. 5.

FIG. 7 is an isometric view of metal strips during the process of making the housing of FIG. 2

FIG. 8 is an isometric view of the metal strips of FIG. 7 with notches.

FIG. 9 is an isometric view of a metal strip assembly during the process of making the housing of FIG. 2

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series and the like. The term “coupled” when utilized, means “either a direct electrical connection between the things that are connected, or an indirect connection through one or more passive or active intermediary devices, but not necessarily limited to”.

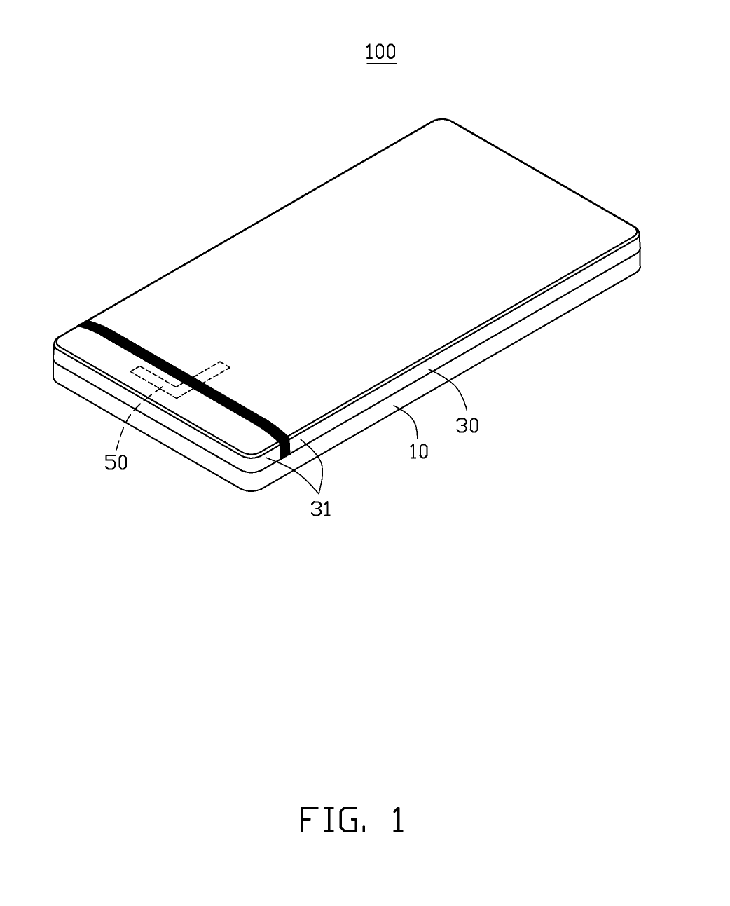

FIG. 1 illustrates an electronic device 100 according to an exemplary embodiment. The electronic device 100 can be, but not limited to, a mobile phone, a personal digital assistant or a panel computer. The electronic device 100 includes a main body 10, a housing 30 assembled to the main body 10, and an antenna 50 located inside the housing 30.

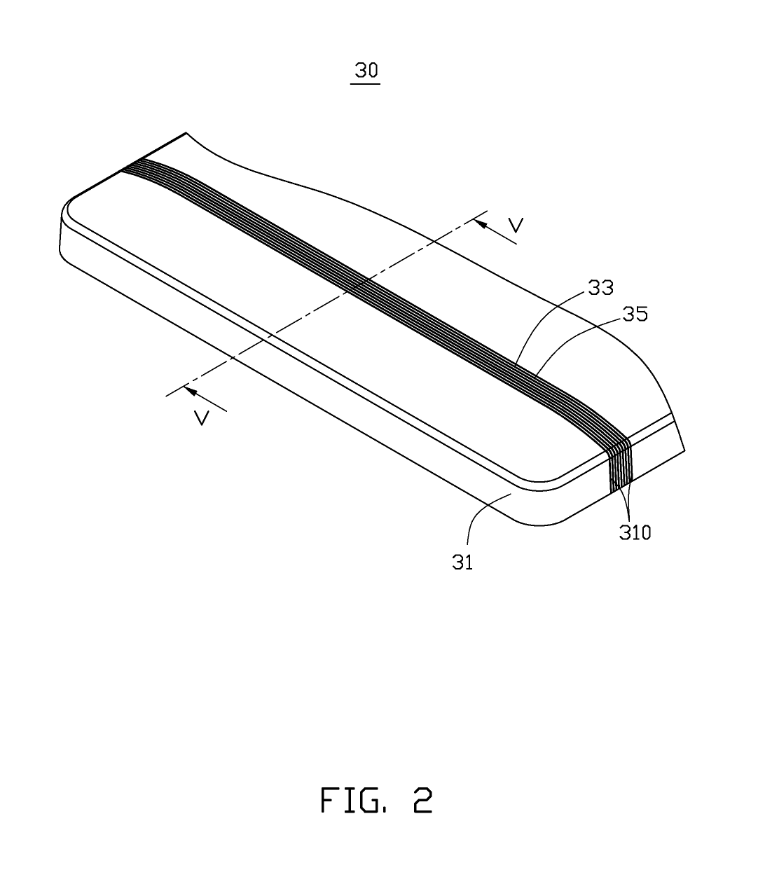

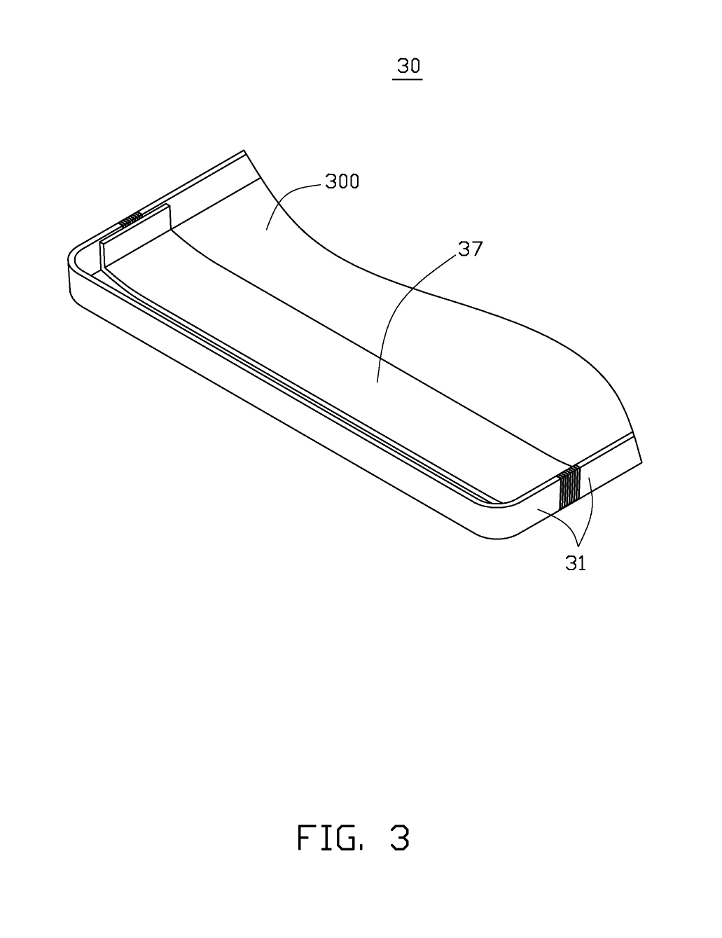

FIGS. 2 and 3 illustrate in one exemplary embodiment, the housing 30 can be a back cover of the electronic device 100. The housing 30 includes a base 31, at least one metal strip 33, at least two non-conductive members 35, and a combining layer 37 formed on the base 31. In this exemplary embodiment, the housing 30 includes a plurality of metal strips 33 and a plurality of non-conductive members 35. The base 31 further defines a receiving space 300 cooperating with main body 10 to receive internal elements of the electronic device 100, such as the antenna 50, battery (not shown) and so on.

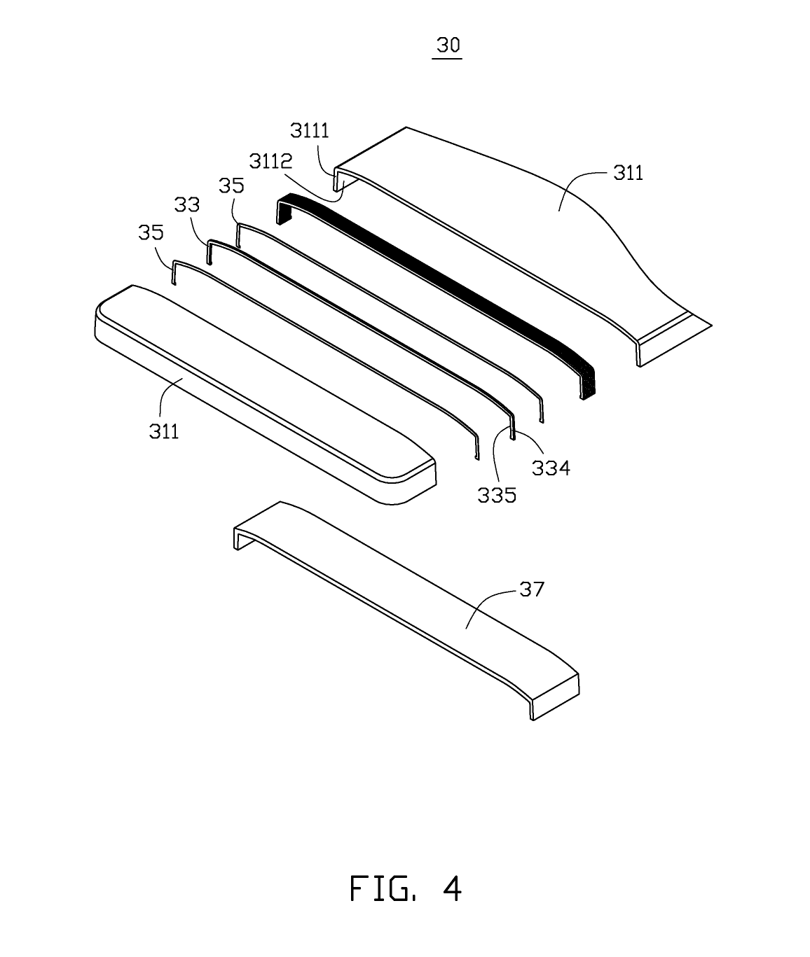

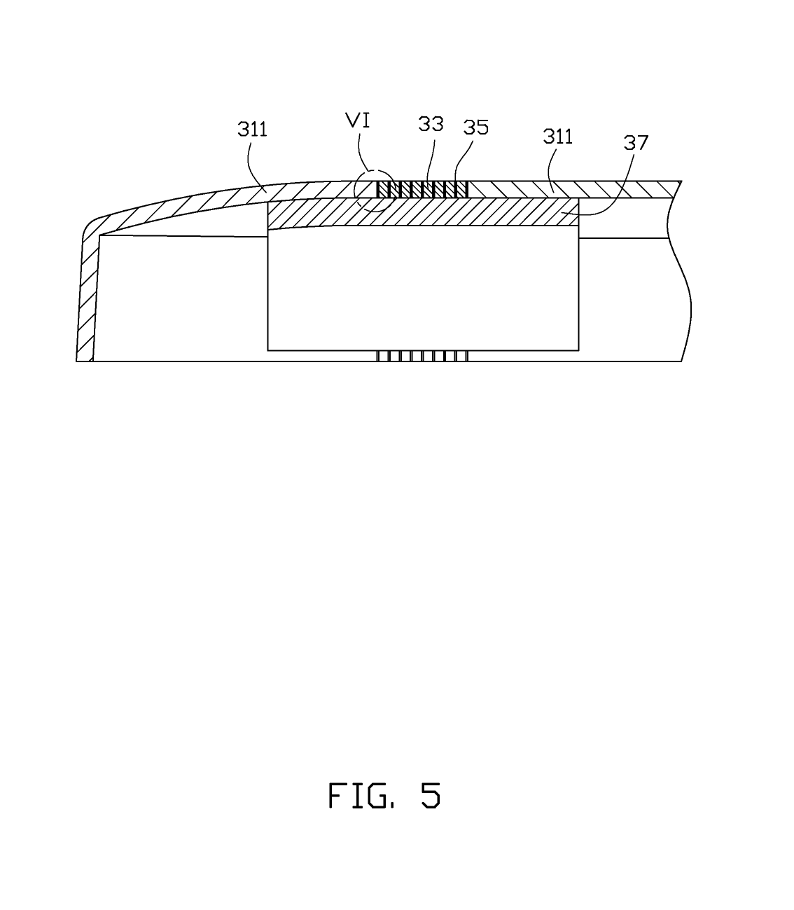

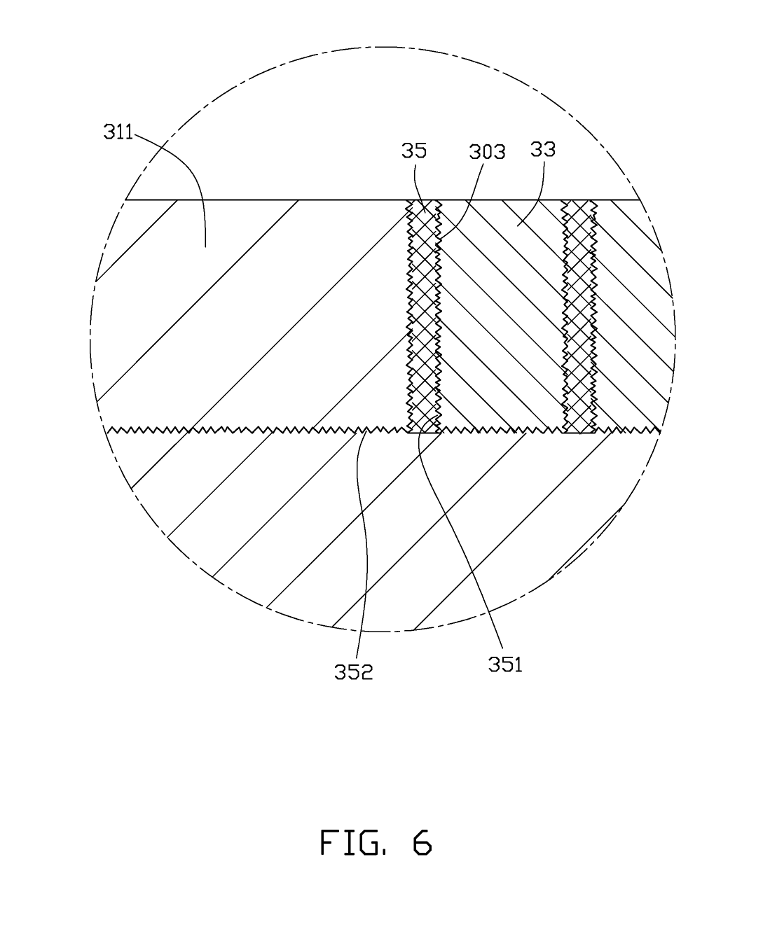

FIGS. 4 and 5 illustrate the base 31 is three-dimensional. In one exemplary embodiment, the base 31 has a substantially U-shaped cross-section. At least one opening 310 is defined in the base 31 corresponding the antenna 50 received in the receiving space 301 and running through an outer surface and an inner surface of the base 31. The at least one opening 310 divides the base 31 into at least two main portions 311. The at least two main portions 311 can be separated from each other or connected to each other through at least one portion of the base 31 adjacent to the openings 30. In one exemplary embodiment, the base 31 includes one opening 310 (shown in FIG. 6) dividing the base 31 into two separated main portions 311. The base 31 is made of metal. The metal can be selected from a group consisting of aluminum alloy, titanium alloy, magnesium alloy, and stainless steel.

The metal strips 33 and the non-inductive members 35 are received in the opening 310 and sandwiched between the two main portions 311. Each metal strip 33 alternates with one non-inductive member 35. Each two adjacent metal strips 33 are connected to each other by one non-inductive member 35 located between the two metal strips 33. A non-inductive member 35 is positioned between each main portion 310 and a metal strip 33 adjacent to the main portion 311, thereby combining the main portions 311 with the metal strips 33 adjacent to the main portions 311. Each main portion 311 is physically but not electrically connected (i.e. dielectrically connected) to the corresponding adjacent metal strips 33. Each metal strip 33 has a thickness of about 0.1 mm to about 1.0 mm along a direction from an adjacent non-conductive member 35 located at one side of the metal strip 33 to another adjacent non-conductive member 35 located at an opposite side of the metal strip 33. Each non-conductive member 35 has a thickness of about 20 μm to about 800 μm along a direction from a metal strip 33 located at one sided of non-conductive member 35 to another adjacent metal strip 33 located at an opposite side of the non-conductive member 35, thereby creating a distance between each two adjacent metal strips 33 and a distance between each main portion 311 and the adjacent metal strip 33 both of about 20 μm to about 800 μm. In other exemplary embodiments, the thickness of each non-conductive member 35 is about 150 μm. Therefore, interference from the metal housing 30 to the antenna 50 can be reduced.

The metal strips 33 are substantially U-shaped corresponding to the main portions 311. Each non-conductive member 35 is adhered to adjacent metal strips 33. Each non-conductive member 35 is also substantially U-shaped to engage with the shape of the metal strips 33.

Each metal strip 33 is made of metal selected from a group consisting of aluminum alloy, titanium alloy, magnesium alloy, and stainless steel.

The non-conductive members 35 can be made of a plastic, glass, or other non-conductive materials. The plastic can be selected from one or more groups consisting of polyphenylene sulfide (PPS), polybutylene terephthalate (PBT), polyamide (PA), polyethylene terephthalate (PET), polytrimethylene terephthalate (PTT), polyetherimide (PEI), polyether ether ketone (PEEK), poly(ethylene-co-1,4-cyclohexylenedimethylene terephthalate) (PCT), and their modified materials.

Also referring to FIG. 4, an end portion of each main portion 311 includes a first side surface 3011 facing the metal strips 33 and a first inner surface 3112 adjacent to the first side surface 3111. Each metal strip 33 includes two opposite second side surfaces 334 and a second inner surface 335 adjacent to the second side surfaces 334. FIG. 6 illustrates a plurality of holes 303 are defined in the first side surface 3111, the first inner surface 3112, the second side surface 334, and the second inner surface 335. The holes 303 can be micropores or nanopores. In this exemplary embodiment, a diameter of each hole 303 is about 15 μm to about 800 μm. In other embodiments, the diameter of each hole 303 can be about 20 nm to about 400 nm. Each non-conductive member 35 includes a plurality of ribs 351 protruding from a surface of the non-conductive member 35. The ribs 351 are configured to be embedded and fixed into the corresponding holes 303.

The combining layer 37 is formed on the internal surface of the base 31 (i.e. a surface of the base 31 facing the main body 10). The combining layer 37 covers each metal strip 33, each non-conductive member 35, and entirely or partially covers an end portion of each main portion 311 connected to the non-conductive member 35. As such, the main portions 311, the metal strips 33, the non-conductive members 35, and the non-conductive member 35 are bonded together through the combining layer 37. The combining layer 37 can further enhance a bonding strength among the main portions 311, the metal strips 33, and the non-conductive members 35, respectively. The combining layer 37 is plastic material, and the plastic material can be selected one or more from a group consisting of polyphenylene sulfide (PPS), polybutylene terephthalate (PBT), polyamide (PA), polyethylene terephthalate (PET), polytrimethylene terephthalate (PTT), polyetherimide (PEI), polyether ether ketone (PEEK), poly(ethylene-co-1,4-cyclohexylenedimethylene terephthalate) (PCT), and their modified materials.

When the housing 30 is assembled to the main body 10, the assembly formed by the metal strips 33 and the non-conductive members 35 is corresponding to the antenna 50. The base 31 can be coupled with the antenna and serve as an extra antenna of the electronic device 100. In addition, signals of the antenna 50 can pass through the non-conductive members 35. Therefore, radiation efficiency of antenna 50 can be increased.

In another embodiment, the base 31 are not coupled with the antenna and does not serve as the extra antenna. The signals of the antenna 50 can pass through the non-conductive members 35 to increase the radiation efficiency of antenna 50.

An exemplary method for making the housing 30 can include the following steps.

The base 31 having three-dimensions is provided. The base 31 defines an opening 310 communicating through the base 31 and corresponding to the antenna 50. The opening 310 divides the base 31 into the two main portions 311. The main portions 311 are separated from each other or connected to each other through at least one portion of the base 31 adjacent to the openings 30. An end portion of each main portion 311 includes a first side surface 3111 facing another main portion 311 and a first inner surface 3112 adjacent to the first side surface 3111. The base 31 can be made by casting, punching, or computer numerical control. The base 31 is made of metal. The metal can be selected from a group consisting of aluminum alloy, titanium alloy, magnesium alloy, and stainless steel.

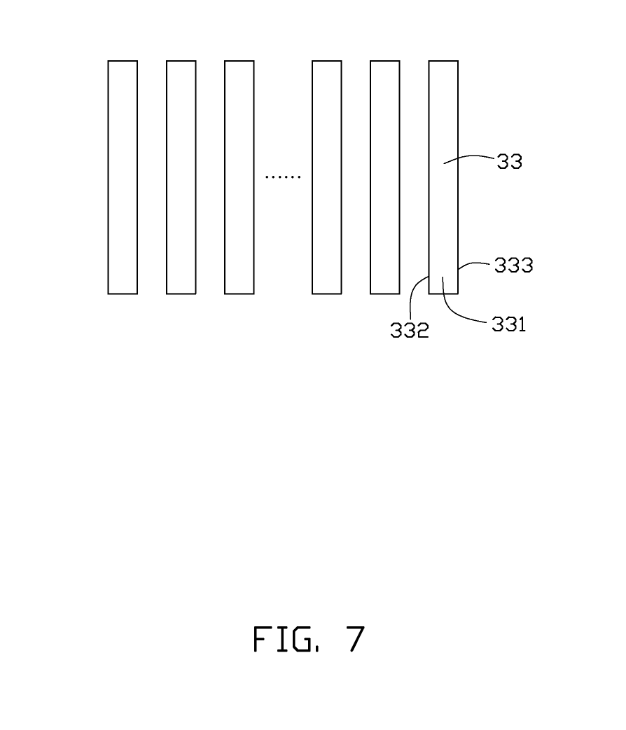

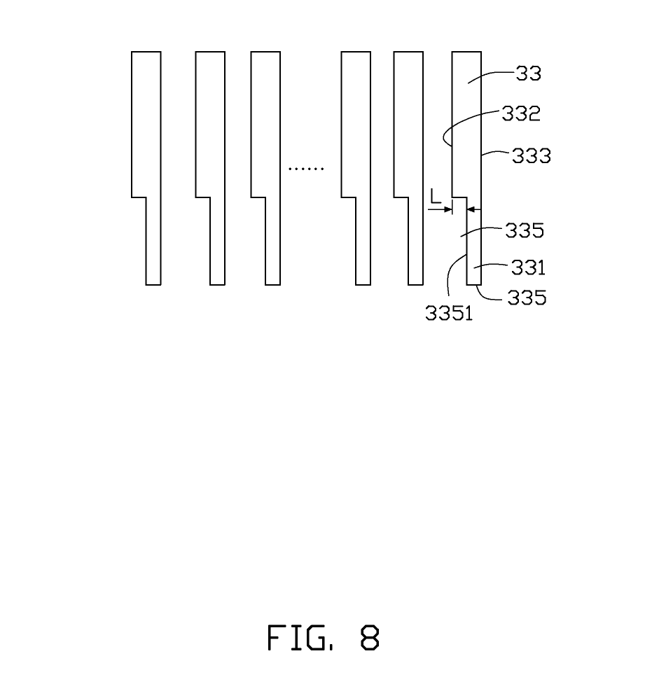

FIGS. 7, 8 and 9 illustrate at least one metal strip 33 or a plurality of metal strips 33 is provided. A notch 335 is defined in each metal strip 33. In one exemplary embodiment, each metal strip 33 includes a machined portion 331. The machined portion 331 is positioned at an end of each metal strip 33. The machined portion 331 includes a first surface 332, a second surface 333, and an inner surface 335 adjacent to the first and second surfaces 332, 333. The first surface 332 of each metal strip 33 is milled to form a notch 335 (shown in FIG. 8). In this exemplary embodiment, the notch 335 is substantially a rectangular cutoff positioned at a corner of said metal strip 33. Each metal strip 33 includes a bottom wall 3351 at the notch 335 opposite to the second surface 333. A width L of the notch 335 along a direction from the first surface 332 to the second surface 333 is about 20 μm to about 800 μm. In one exemplary embodiment, the width L of the notch 335 is 150 μm. A distance between the bottom 3351 and the second surface 333 is about 0.1 mm to about 1.0 mm. The metal strips 33 are made of metal selected from a group consisting of aluminum alloy, titanium alloy, magnesium alloy, and stainless steel.

A plurality of holes is defined in the first side surface 3111, the first inner surface 302, each surface of the machined portion 331. In this exemplary embodiment, the plurality of holes are formed on the first side surface 3111, the first inner surface 302, and each surface of the machined portion 331 by solution impregnation, electrochemical etching, chemical etching or anodic oxidation. The holes 303 can be micropores or nanopores. In this exemplary embodiment, a diameter of each hole 303 is about 15 μm to about 800 μm. In other embodiments, the diameter of each hole 303 can be about 20 nm to about 400 nm.

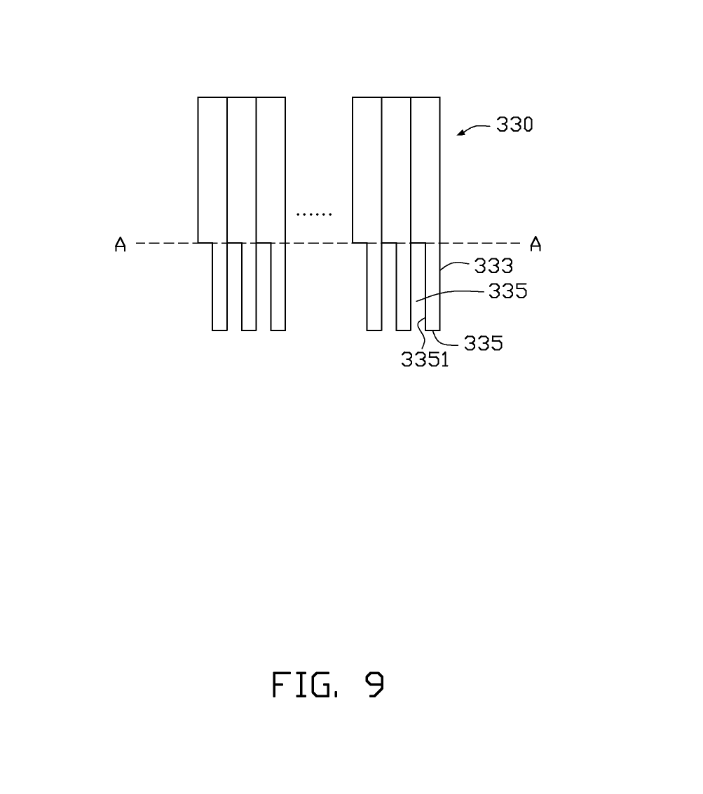

FIG. 9 illustrate the metal strips 33 are joined together to form a metal strip assembly 330 with the notch 335 of each metal strip 33 positioned at a same end. The joined metal strip assembly 330 is inserted into the opening 310. An end of each metal strip 33 has the notch 335 facing the inner surface of the base 31. A plurality of non-conductive members 35 are formed by injection molding.

In this exemplary embodiment, the base 31 is placed in a mold for forming (not shown). The jointed metal strip assembly 330 is inserted into the opening 310. A plurality of gaps (not shown) is defined between the metal strip assembly 330 and the main portions 311. The notches 335 are positioned between the metal strips 33 facing the inner surface of the base 31. Liquid molten plastic is injected into the forming mold. The Liquid molten plastic is filled into the notches 335 and the gaps between each main portion 311 and the metal strip assembly 330, and also covers the first inner surface 3112 of each main portion 311 and each second inner surface 335 of each metal strip 33. After cooling, the plastic is solidified to form a plurality of non-conductive members 35 filled in the notches 33 and the gaps between each main portion 311 and the metal strip assembly 330, and also forms a combing layer 37 covering each metal strip 33, each non-conductive member 35, and entirely or partially covering an end portion of each main portion 311 connected to the non-conductive member 35. The combining layer 37 can further enhance a bonding strength among the main portions 311, the metal strips 33, and the non-conductive members 35, respectively.

A redundant portion of each metal strip 33 exposed from the outer surface of the base 31 can be removed by numerical control machines. For example, the redundant portion of each metal strip 33 at least includes a portion of each metal strip 33 positioned above a broken line A-A as shown in FIG. 9 (i.e. a portion of each metal strip 33 except for the machined portion 331). As such, the metal strips 33 and the base 31 can obtain a smooth appearance to from the housing 30. Finally, the housing 30 can be polished or decorated.

In other embodiments, the combining layer 37 can be formed by a secondary injection molding. That is, the non-conductive members 35 are formed by a first injection molding, and the combining layer 37 is formed by a second injection molding.

In addition, while injecting the plastics into the mold, the non-conductive members 35 are also embedded into the holes 303 of the main portions 311 and the metal strips 33 to form a plurality of ribs 351, 352.

The housing 30 forms the plurality of metal strips 33 and the plurality of non-conductive members 35 corresponding to the antenna 50 to reduce interference from the housing 30 to the antenna 50. In addition, the base 31 can be coupled with the antenna 50 to serve as an extra antenna of the electronic device 100 to increase the radiation efficiency of the antenna 50. The non-conductive members 35 partially embedded into the holes 303 are defined in each main portion 311 and each metal strip and the combining layer 37 formed on the inner surface of the base 31 enhance the bonding strength among the main portion 311, the metal strips 35, and the non-conductive members 35, respectively.

It is to be understood, however, that even through numerous characteristics and advantages of the present disclosure have been set forth in the foregoing description, together with details of assembly and function, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A housing, comprising:
a base,
the base having a plurality of main portions separated by one or more portions having a plurality of openings formed therein, each of the plurality of openings having a metal strip therebetween thereby forming a series of openings and metal strips, each of the openings having non-conductive members being formed therein, the metal strips fixed together by the non-conductive members to form a metal strip assembly, and
wherein the metal strips and the main portions are fixed together by the non-conductive members.

2. The housing as claimed in claim 1, wherein the metal strips and the main portions are dielectrically connected by the non-conductive members.

3. The housing as claimed in claim 1, wherein the plurality of openings divide the base into at least two main portions, the at least two main portions are separated from each other or connected to each other through at least one portion of the base adjacent to the openings.

4. The housing as claimed in claim 1, wherein each surface of each metal strip attached to the non-conductive members defines a plurality of holes, each surface of each non-conductive member attached to the metal strips comprises a plurality of ribs, the ribs are embedded and fixed into the holes.

5. The housing as claimed in claim 4, wherein a diameter of each hole is about 15 μm to about 800 μm.

6. The housing as claimed in claim 1, wherein a surface of each non-conductive member attached to the main portion comprises a plurality of ribs, a side surface of each main portion defines a plurality of holes, the ribs are embedded and fixed into the holes.

7. The housing as claimed in claim 6, wherein a diameter of each hole is about 15 μm to about 800 μm.

8. The housing as claimed in claim 1, wherein each metal strip has a thickness of about 0.1 mm to about 1.0 mm along a direction from an adjacent non-conductive member located at one sided of the metal strip to another adjacent non-conductive member located at an opposite side of the metal strip.

9. The housing as claimed in claim 1, wherein each non-conductive member has a thickness of about 20 μm to about 800 μm along a direction from a metal strip located at one sided of non-conductive member to another adjacent metal strip located at an opposite side of the non-conductive member.

10. The housing as claimed in claim 1, wherein the base further comprises a combining layer formed on the base, the combining layer covers the metal strips, the non-conductive members, and totally or partly covers an end of the main portion connected with the insulating layers.

11. The housing as claimed in claim 10, wherein each metal strip and each main portion both comprises an inner surface defining a plurality of holes, an inner surface of the combining layer covering the metal strips and the main portions comprises a plurality of ribs, the ribs are embedded and fixed into the holes.

12. The housing as claimed in claim 1, wherein a diameter of each hole is about 15 μm to about 800 μm.

13. The housing as claimed in claim 1, wherein the non-conductive members are made of plastic selected one or more from a group consisting of polyphenylene sulfide, polybutylene terephthalate, polyamidepolyamide, polyethylene terephthalate, polytrimethylene terephthalate, polyetherimide, polyether ether ketone, poly(ethylene-co-1,4-cyclohexylenedimethylene terephthalate), and their modified materials.

14. A method of making a housing comprising:
providing a base defining a plurality of opening;
providing a plurality of metal strips, each end of each metal strip defining a notch, jointing the metal strips together to form a metal strip assembly with each end having the notch positioned at a same end, inserting the metal strip assembly into one of the openings with the notches facing an inner surface of the base;
placing the base and the metal strip assembly in a mold;
injecting liquid molten plastics into the mold so that the plastics is filled into the notches.

15. The method as claimed in claim 14, wherein the plurality of openings divide the base into at least two main portions, the at least two main portions are separated from each other or connected to each other through at least one portion of the base adjacent to the openings.

16. The method as claimed in claim 14, wherein each main portion comprises a side surface and an inner surface adjacent to the side surface, the side surface, the inner surface of each main portion, and the end of each metal strip having the notch define a plurality of holes by solution impregnation, electrochemical etching, chemical etching or anodic oxidation, before the step of injection molding.

17. The method as claimed in claim 14, wherein in the step of injection molding, a portion of the plastics are filled into the holes to form a plurality of ribs.

18. The method as claimed in claim 14, wherein in the step of injection molding, a portion of the plastics covering an inner surface of each metal strip and entirely or partially covering an end portion of the base to form a combining layer.

19. An electronic device, comprising:
a main body, a housing mounted on the main body, and an antenna assembled in the housing; and
the housing is as claimed in claim 1; and
the metal strip assembly is corresponding to the antenna, signals of the antenna passing through the metal strip assembly.

20. The electronic device as claimed in claim 19, wherein each surface of each metal strip attached to the non-conductive members defines a plurality of holes, each surface of each non-conductive member attached to the metal strips comprises a plurality of ribs, the ribs are embedded and fixed into the holes.
